(19) United States
(12) Patent Application Publication
(10) Pub. No.: US 2010/0087065 A1
(43) Pub. Date: Apr. 8, 2010

(54) STABILIZATION OF POLYMER-SILICA DISPERSIONS FOR CHEMICAL MECHANICAL POLISHING SLURRY APPLICATIONS

(75) Inventors: Karl E. Boggs, Hopewell Junction, NY (US); Jeffrey Giles, Watertown, CT (US); Michael S. Darsillo, Landenberg, PA (US); Melissa A. Petruska, Newtown, CT (US); Peter Wrschka, Phoenix, AZ (US)

Correspondence Address: MOORE & VAN ALLEN PLLC, P.O. BOX 13706, Research Triangle Park, NC, 27709, US

(73) Assignee: ADVANCED TECHNOLOGY MATERIALS, INC., Danbury, CT (US)

(21) Appl. No.: 12/525,325

(22) PCT Filed: Jan. 31, 2008
(86) PCT No.: PCT/US08/52614

§ 371 Date: Oct. 12, 2009

Related U.S. Application Data
(60) Provisional application No. 60/887,435, filed on Jan. 31, 2007.

(51) Int. Cl. C09K 13/00; H01L 21/461

(52) U.S. Cl. 438/692; 252/79.1

(57) ABSTRACT

Chemical mechanical polishing (CMP) compositions and single CMP platen process for the removal of copper and barrier layer material from a microelectronic device substrate having same thereon. The process includes the in situ transformation of a copper removal CMP composition, which is used to selectively remove and planarize copper, into a barrier removal CMP composition, which is used to selectively remove barrier layer material, on a single CMP platen pad.

### FIELD OF THE INVENTION

The present invention relates to chemical mechanical polishing compositions and processes for the polishing of semiconductor substrates having metal patterns, e.g., copper interconnects, copper electrodes, or other device metallization, which can include a barrier layer material as part of the structure thereon.

### DESCRIPTION OF THE RELATED ART

Copper is employed in semiconductor manufacturing as a material of construction for components of semiconductor device structures (e.g., wiring, electrodes, bond pads, conductive vias, contacts, field emitter base layers, etc.) on wafer substrates, and it is rapidly becoming the interconnect metal of choice in semiconductor manufacturing due to its higher conductivity and increased electromigration resistance relative to aluminum and aluminum alloys.

Typically, the process scheme for incorporating copper in semiconductor manufacturing involves the damascene approach, wherein features are etched in a dielectric material, filled in with blanket metallization, and the surface metallization removed to isolate the features. In the dual damascene process a single fill is used to form both plugs and lines. Since copper has a propensity to diffuse into the dielectric material, which can lead to leakage between metal lines and migration into the transistor structure, barrier/liner layers, such as Ta and/or TaN, are often used to seal the copper interconnects. Following deposition of the barrier layer material, a thin seed layer of copper is deposited on the liner material via physical or chemical vapor deposition, followed by electro deposition of copper to fill the features.

As copper is deposited to fill the etched features, elevational disparity or topography develops across the surface of the layer having raised and recessed regions. The deposited copper overburden and the barrier material in the up areas must then be removed to electrically isolate the individual features of the circuitry and to render it of suitable form to accommodate subsequent process steps in the fabrication of the finished semiconductor product, and in order to satisfactorily operate in the micro-circuitry in which it is present. The planarization typically involves chemical mechanical polishing (CMP) using a CMP composition formulated for such purpose.

Chemical mechanical polishing or planarization is a process in which material is removed from a surface of a semiconductor wafer, and the surface is polished (planarized) by coupling a physical process such as abrasion with a chemical process such as oxidation or chelation. In its most rudimentary form, CMP involves applying slurry, specifically a solution of an abrasive and an active chemistry, to a wafer surface or polishing pad that polishes the different materials on the surface structure of the semiconductor wafer to achieve both the removal of unwanted material and planarization of the wafer surface. It is not desirable for the removal or polishing process to be purely physical or purely chemical, but rather the synergistic combination of both is preferred in order to achieve fast, uniform removal and a planar surface of the materials of construction.

Due to the difference in chemical reactivity between copper and the barrier layer, e.g., Ta and/or TaN, two chemically and mechanically distinct slurries are often used in the copper CMP process. The copper removal slurry is used to rapidly planarize the topography and to uniformly remove the copper, with the copper removal polish stopping at the barrier layer. Often the copper removal process (and slurry) can be subdivided into a bulk copper removal process and a soft landing process. Depending on the requirements, the bulk copper removal process and the soft landing process may require the use of two distinct slurries or the same slurry. Typically the ratio of copper removal rate to barrier layer removal rate during the copper removal CMP polishing steps is greater than 100:1. The barrier removal slurry removes the barrier layer material at a high removal rate and stops in or at the dielectric layer, or alternatively stops in or at a cap layer that has been applied to protect the dielectric. Typically, the ratio of barrier layer removal rate to copper removal rate during barrier removal process is selected based on integration requirements.

Previously, the present inventors discovered that the inclusion of a rheology agent containing functional groups capable of hydrogen bonding in a CMP slurry including alumina modifies the slurry's fluid dynamics and as such, improved the material selectivity of the CMP process while maintaining a high level of copper planarization, efficiency, and good uniformity. Unfortunately, the incorporation of said rheology agent in a CMP slurry including silica either flocculated the silica or had no effect on the rheology of the slurry.

Towards that end, it is an object of this invention to provide a CMP slurry suitable for metal, e.g., copper or copper-containing material, removal and/or soft landing processes comprising a polymeric additive that minimizes flocculation of silica abrasives in said CMP slurry, thus providing increased planarization efficiency, increasing selectivity to the barrier/liner layer, lowering overall dishing and lowering the rate of dishing.

### SUMMARY OF THE INVENTION

The present invention relates to chemical mechanical polishing (CMP) compositions and processes for the polishing of microelectronic device substrates having metal and barrier layer material thereon. Specifically, the present invention relates to a CMP slurry composition including additive that minimizes flocculation of silica abrasives in said CMP slurry.

In one aspect, the invention relates to a copper removal CMP slurry composition with increased planarization efficiency of copper films, comprising at least one abrasive agent, at least one solvent, at least one passivating agent and at least one anti-flocculating agent. Preferably, the at least one anti-flocculating agent is a polymeric additive, selected from the group consisting of polyvinylpyrrolidone, polymers including N-vinyl pyrrolidone monomers, and combinations thereof.

In another aspect, the invention relates to a copper removal CMP slurry composition with increased planarization efficiency of copper films, comprising at least one abrasive agent, at least one solvent, at least one passivating agent, at least one chelating agent, at least one rheology agent, at least one buffering agent, and at least one polymeric additive. Preferably, the at least one polymeric additive is selected from the group consisting of polyvinylpyrrolidone, polymers including N-vinyl pyrrolidone monomers, and combinations thereof.

In still another aspect, the invention relates to a copper removal CMP slurry composition with increased planarization efficiency of copper films, comprising at least one abrasive component, at least one solvent, at least one passivating agent, at least one polymeric additive, at least one chelating agent, at least one antimicrobial agent, at least one defoaming agent, at least one rheology agent, and at least one buffering agent. Preferably, the at least one polymeric additive is selected from the group consisting of polyvinylpyrrolidone, polymers including N-vinyl pyrrolidone monomers, and combinations thereof.

In yet another aspect, the invention relates to a copper removal CMP slurry composition comprising, consisting of, or consisting essentially of silica, 1,2,4-triazole, polyvinylpyrrolidone, glycine, hydroxypropylcellulose, hydrogen peroxide, water, optionally buffering agent, optionally biocide and optionally defoamer.

Still another aspect of the invention relates to a method of polishing a wafer substrate at a platen, said method comprising contacting said wafer substrate having metal thereon for sufficient time and under at least one metal removal CMP condition with at least one metal removal CMP slurry composition to substantially remove metal from said wafer and expose said barrier material, wherein said CMP slurry composition comprises at least one abrasive component, at least one solvent, at least one passivating agent, and at least one polymeric additive. Preferably, the at least one polymeric additive is selected from the group consisting of polyvinylpyrrolidone, polymers including N-vinyl pyrrolidone monomers, and combinations thereof.

Another aspect of the invention relates to a method of polishing a wafer substrate having metal and a barrier layer material deposited thereon at a platen, said method comprising

contacting said microelectronic device substrate having metal thereon on the platen for sufficient time and under metal removal CMP conditions with at least one metal removal CMP composition to substantially remove metal from the microelectronic device substrate and expose barrier layer material, wherein at least one metal removal CMP composition comprises at least one abrasive, at least one solvent, at least one passivating agent and at least one polymeric additive; and

contacting the microelectronic device substrate having barrier layer material thereon on the same platen for sufficient time and under barrier removal CMP conditions with a barrier removal CMP composition to substantially remove barrier layer material from the microelectronic device substrate, wherein the barrier removal CMP composition comprises at least one passivating agent, at least one barrier layer removal enhancer, at least one selectivity additive, at least one solvent, at least one acid-stable abrasive, and optionally at least one oxidizing agent.

Still another aspect of the invention relates to a kit comprising, in one or more containers, copper removal CMP composition reagents, wherein the copper removal CMP composition comprises at least one passivating agent, at least one polymeric additive, at least one abrasive agent and at least one solvent, and wherein one or more additional components suitable for combination with the copper removal CMP composition to form a barrier removal CMP composition are optionally included in one or more containers, wherein the one or more additional components are selected from the group consisting of at least one barrier layer removal enhancer, at least one selectivity enhancer, and combinations thereof.

In still another aspect, the invention relates to a method of stabilizing chemical mechanical polishing (CMP) formulations against flocculation from hydrogen bonding mechanisms, said method comprising adding a polymeric additive to a CMP composition including at least one metal oxide abrasive containing hydroxyl groups and at least one additive that causes bridging flocculation.

In yet another aspect, the invention relates to an etching composition comprising a metal oxide abrasive containing hydroxyl groups, an additive that causes bridging flocculation selected from the group consisting of water soluble polymers (WSPs) and cross-linked acrylic acid based polymers, and an anti-flocculating agent.

Another aspect of the invention relates to an article of manufacture comprising a copper removal CMP composition, and a microelectronic device, wherein the copper removal CMP composition includes at least one abrasive agent, at least one solvent, at least one passivating agent and at least one polymeric additive.

In a further aspect, the present invention relates to a method of manufacturing a microelectronic device, said method comprising contacting said a wafer substrate having metal thereon for sufficient time and under at least one metal removal CMP condition with at least one metal removal CMP composition to substantially remove metal from said wafer and expose barrier material, wherein at least one metal removal CMP composition includes at least one abrasive agent, at least one solvent, at least one passivating agent and at least one polymeric additive. It should be appreciated that the wafer substrate will eventually be incorporated in the microelectronic device.

Yet another aspect of the invention relates to improved microelectronic devices, and products incorporating same, made using the methods of the invention comprising removing metal from a wafer to expose barrier material, using the methods and/or compositions described herein, and optionally, incorporating the microelectronic device into a product.

Other aspects, embodiments and features of the invention will be more fully apparent from the ensuing disclosure and appended claims.

### BRIEF DESCRIPTION OF THE DRAWINGS

FIG. 1 shows a depiction of laminar flow consistent with the meaning of the term as used herein.

FIGS. 2a and 2b illustrate one affect of a rheology agent on laminar flow in a CMP process according to one embodiment of the present invention.

FIG. 3 illustrates the dishing of a 80 μm copper bond pad (in Angstroms) as a function of overpolishing after the tool endpoint (in seconds) using the composition of the invention.

FIG. 4 illustrates the erosion of a 50% pattern density 0.18 micron array (in Angstroms) as a function of overpolishing after the tool endpoint (in seconds) using the composition of the invention.

### DETAILED DESCRIPTION OF THE INVENTION

The present invention relates to chemical mechanical polishing (CMP) compositions and processes for the polishing of microelectronic device substrates having metal, e.g., copper, and barrier layer material thereon. More specifically, the CMP composition of the invention includes an additive that minimizes flocculation of silica abrasive material in the presence of rheology agents that contain functional groups capable of hydrogen bonding. Additionally, the present invention relates to the in situ transformation of a copper removal polishing composition into a barrier removal polishing composition on a single platen, i.e., without transference of the microelectronic device substrate to another platen for barrier removal processing.

As used herein, “about” is intended to correspond to ±5.0% of the stated value.

For ease of reference, “microelectronic device” corresponds to semiconductor substrates, wafer substrates, flat panel displays, and microelectromechanical systems (MEMS), manufactured for use in microelectronic, integrated circuit, or computer chip applications. It is to be understood that the term microelectronic device is not meant to be limiting in any way and includes any substrate that will eventually become a microelectronic device, microelectronic assembly, or component thereof.

As defined herein, “dielectric capping material” corresponds to silicon carbide (SiC), silicon carbon nitride (SiCN), silicon carbon oxide (SiCO), silicon oxynitride (SiON), silicon nitride, silicon germanium (SiGe), SiGeB, SiGeC, AlAs, InGaP, InP, InGaAs, and combinations thereof.

As used herein, within wafer non-uniformity (WIWNU) corresponds to a measurement of variation of material removal across the wafer. More specifically, WIWNU is the percent standard deviation of the amount of copper (Cu) removed for 49 measurement points, relative to the average amount of Cu removed for the 49 measurement points. Preferably, the WIWNU is less than about 5%.

As used herein, the term “substantially remove” corresponds to the removal of the referenced material such that greater than 50% of the underlying material between features has been exposed, preferably greater than 90% exposed, even more preferably greater than 95% exposed, and most preferably greater than 99% exposed, following the specific CMP processing step. For example, the CMP removal process of the present invention preferably exposes greater than 99% of the underlying barrier between features at the completion of the processing step.

As defined herein, the term “barrier layer material,” also known as “liner material,” corresponds to any material used in the art to seal the metal lines, e.g., copper interconnects, to minimize the diffusion of said metal, e.g., copper, into the dielectric material. Preferred barrier layer materials include tantalum, titanium, ruthenium, hafnium, tungsten, and other refractory metals as well as nitrides and/or silicides of any of these metals. Specific reference to tantalum hereinafter in the broad description of the invention is meant to provide an illustrative example only of the present invention and does not limit in any way the full scope of the invention.

As defined herein, the “bulk metal” corresponds to the metal interconnect material, e.g., lines and vias on the microelectronic device. Metals include, but are not limited to, aluminum, copper, aluminum-copper, tungsten, ruthenium, gold, silver, palladium, platinum, and combinations thereof. It is to be understood that specific reference to copper hereinafter in the broad description of the invention is meant to provide an illustrative example only of the present invention and does not limit in any way the full scope of the invention.

In CMP, slurries are formulated to independently control the relative polishing rates between the different materials of the pattern to be polished. For example, a CMP slurry such as that of the present invention is used to rapidly remove bulk copper and to uniformly planarize the topography. A barrier removal CMP slurry can also be used to remove the barrier layer material and optionally part of the cap and/or dielectric layer(s). Typically, the microelectronic device substrate having the copper layer and barrier layer material is positioned on a first platen for a polishing to remove and planarize the copper layer and then subsequently transferred to another platen for a polishing to remove the barrier layer material. In certain applications, the use of an additional platen for the second polishing may be disadvantageous in part due to throughput considerations as well as tool constraints.

To chemically mechanically polish the microelectronic device substrate on a single platen requires the sequential introduction of at least one copper removal CMP slurry and a barrier removal CMP slurry to the same platen. Even with a rinse in between the introduction of the at least two different slurries to the same platen, pH shock, incompatibility between chemistries and/or abrasives, flocculation of abrasives, and other problems degrade polish performance or cause greatly diminished results. For example, generally, copper removal slurries include alumina, which is cationic, and barrier removal slurries include silica, which is anionic. This is why conventional CMP processes include copper removal using the at least one copper removal slurry on one or more platens followed by transference of the substrate to another platen for barrier layer material removal using the barrier removal slurry.

The present invention overcomes the problems associated with prior art single platen CMP formulations and processes. Specifically, the present invention relates to improved copper removal CMP compositions that minimize flocculation of silica abrasives while exhibiting increased planarization efficiency, increasing selectivity to the Ta layer, lowering overall dishing and the overall rate of dishing. Advantageously, the improved copper removal slurry is compatible with barrier removal slurries and as such, the improved copper removal slurry composition and the barrier removal composition may be sequentially introduced to the same platen. The CMP compositions and process described herein ensure the rapid, efficient and selective removal and planarization of bulk copper as well as the selective removal of residual copper, barrier layer material, and optionally partial removal of the dielectric stack, wherein both the copper removal and barrier removal processing may be effectuated on the same platen.

Alternatively, it is also within the scope of the present invention that the improved copper removal polishing composition and the barrier removal composition may be applied at different platens for multiple platen polishing, as conventionally used in the art. In other words, the copper removal polishing composition may be applied to a platen for the removal of copper and the barrier removal composition may be applied at a different platen for the removal of barrier layer materials.

As defined herein, “copper removal” corresponds to the CMP process of removing and planarizing bulk copper from the surface of a substrate having bulk copper thereon, as well as the slurry formulation used during said CMP process. The copper removal process may include “soft landing” or “touchdown,” which corresponds to some point in the copper removal polishing process whereby the downforce of the polisher may be decreased or the copper removal composition may be altered to reduce dishing and/or erosion of the copper on the surface of the substrate. The copper removal process may also include “over-polishing.” “Soft landing” or “touchdown” is preferably ceased at a detectable or predetermined processing endpoint. Upon reaching the endpoint, over-polishing may begin. Over-polishing is performed to remove the copper residuals from the surface of the barrier material, while minimizing additional dishing or erosion of the copper features.

As defined herein, “barrier removal” corresponds to the CMP process of removing residual copper, barrier layer material, a dielectric capping material such as SiON or optionally some dielectric from the surface of a microelectronic device substrate having same thereon, as well as the slurry formulation used during said CMP process. Often the barrier removal process is controlled with a fixed process time, but the process may be controlled by means of an endpoint system and may include an over-polishing step after the endpoint of the barrier removal polish has been detected.

In one aspect, the present invention relates to a soft-landing CMP polishing composition for use subsequent to the bulk copper removal process.

In one embodiment, the copper removal CMP polishing composition of the present invention comprises, consists of or consists essentially of at least one abrasive agent, at least one passivating agent, at least one solvent, and at least one polymeric additive. In a preferred embodiment, the copper removal CMP polishing composition of the present invention comprises, consists of or consists essentially of at least one abrasive, at least one passivating agent, at least one solvent, at least one polymeric additive, and at least one chelating agent. In another preferred embodiment, the copper removal CMP polishing composition of the present invention comprises, consists of or consists essentially of at least one abrasive, at least one passivating agent, at least one solvent, at least one polymeric additive, at least one chelating agent, and at least one rheology agent. In still another preferred embodiment, the copper removal CMP polishing composition of the present invention comprises, consists of or consists essentially of at least one abrasive, at least one passivating agent, at least one solvent, at least one polymeric additive, at least one chelating agent, at least one rheology agent, and at least one oxidizing agent. In yet another preferred embodiment, the copper removal CMP polishing composition of the present invention comprises, consists of or consists essentially of at least one abrasive, at least one passivating agent, at least one solvent, at least one polymeric additive, at least one rheology agent, and at least one oxidizing agent. In still another preferred embodiment, the copper removal CMP polishing composition of the present invention comprises, consists of or consists essentially of at least one abrasive, at least one passivating agent, at least one solvent, at least one polymeric additive, at least one chelating agent, and at least one oxidizing agent. In yet another preferred embodiment, the copper removal CMP polishing composition of the present invention comprises, consists of or consists essentially of at least one abrasive, at least one passivating agent, at least one solvent, at least one polymeric additive, at least one chelating agent, at least one rheology agent, at least one defoaming agent, at least one biocide, and at least one oxidizing agent. In each of these embodiments, the copper removal CMP polishing composition may further comprises at least one of the following agents selected from the group consisting of at least one antimicrobial or biocidal agent, at least one defoaming agent, at least one buffering agent, and combinations thereof.

Broadly, a concentrate of the copper removal CMP polishing composition includes the following components, present in following weight percentages, based on the total weight of the composition:

| | | more preferred/% | most preferred/% |
|---|---|---|---|
| Component | % by Weight | by Weight | by Weight |
| Passivating agent(s) | about 0.01% to about 5% | about 0.1% to about 1% | about 0.3% to about 0.6% |
| Polymeric Additive(s) | about 0.01% to about 5% | about 0.02% to about 1% | about 0.02% to about 0.5% |
| Abrasive(s) | about 0.01% to about 25% | about 0.1% to about 5% | about 0.5% to about 1.5% |
| Solvent(s) | about 30% to about 99.4% | about 50% to about 99% | about 75% to about 98% |

When present in the concentrate, the amount of chelating agent(s) is in a range from about 0.01 wt % to about 20 wt %, more preferably about 1 wt % to about 8 wt %, and most preferably about 2 wt % to about 5 wt %; the amount of rheology agent(s) is in a range from about 0.01 wt % to 5 wt %, more preferably about 0.01 wt % to about 1 wt %, and most preferably about 0.05 wt % to about 0.2 wt %; and the amount of oxidizing agent(s) is in a range from about 0.01 wt % to about 30 wt %, more preferably about 1 wt % to about 20 wt %, and most preferably about 2 wt % to about 10 wt %.

Put another way, the range of weight percent ratios for passivating agents relative to polymeric additive(s) is about 0.5:1 to about 20:1, preferably 1:1 to about 10:1; the range of weight percent ratios for abrasive(s) relative to polymeric additive(s) is about 1:1 to about 50:1, preferably 2:1 to about 25:1; when present, the range of weight percent ratios for chelating agent(s) relative to polymeric additives is about 1:1 to 100:1, preferably about 10:1 to 70:1; and when present, the range of weight percent ratio of rheology agent(s) relative to polymeric additive(s) is about 0.1:1 to about 5:1, preferably about 0.5:1 to about 2.5:1. In one embodiment, the weight percent ratios for passivating agents relative to polymeric additive(s) is about 6:1 to about 10:1; the range of weight percent ratios for abrasive(s) relative to polymeric additive(s) is about 16:1 to about 24:1; the range of weight percent ratios for chelating agent(s) relative to polymeric additives is about 50:1 to 65:1; and the range of weight percent ratio of rheology agent(s) relative to polymeric additive(s) is about 1.5:1 to about 2.5:1. In another embodiment, the weight percent ratios for passivating agents relative to polymeric additive(s) is about 1:1 to about 3:1; the range of weight percent ratios for abrasive(s) relative to polymeric additive(s) is about 3:1 to about 7:1; the range of weight percent ratios for chelating agent(s) relative to polymeric additives is about 10:1 to 15:1; and the range of weight percent ratio of rheology agent(s) relative to polymeric additive(s) is about 0.1:1 to about 1:1.

The pH of the copper removal CMP composition is in a range from about 2 to about 12, preferably in a range from about 4 to about 6, even more preferably in a range from about 4.5 to about 5.5, and most preferably about 5.

In general, the specific proportions and amounts of abrasive(s), solvent(s), passivating agent(s), polymeric additive(s), optional chelating agent(s), optional antimicrobial/biocidal agent(s), optional defoaming agent(s), optional rheology agent(s), optional oxidizing agent(s) and optional buffering agent(s), in relation to one another, may be suitably varied to provide the desired removal action of the copper layer from the microelectronic device substrate having same thereon, as readily determinable within the skill of the art without any undue experimentation or effort.

The abrasive component of the copper removal CMP composition as used herein may be of any suitable type, including, without limitation: metallic and solid elemental particles; polymer particles; oxides, fluorides, carbonates, borides, nitrides and hydroxides of Al, Ag, Au, Ca, Ce, Cr, Cu, Fe, Gd, Ge, La, In, Hf, Mn, Ng, Ni, Nd, Pb, Pt, P, Sb, Se, Sn, Th, Ti, Ta, Th, Y, W, Zn, Zr, and mixtures thereof. Specific examples include silica, alumina, silicon carbide, silicon nitride, iron oxide, ceria, zirconium oxide, tin oxide, titanium dioxide, and mixtures of two or more of such components in suitable form, such as grains, granules, particles, or other divided form. Alternatively, the abrasive can include composite particles formed of two or more materials, e.g., NYACOL® alumina-coated colloidal silica (Nyacol Nano Technologies, Inc., Ashland, Mass.) or mixtures of different particle size distributions of said abrasives or any combination thereof. Organic polymer particles, e.g., including thermoset and/or thermoplastic resin(s), can be utilized as abrasives. Useful resins in the broad practice of the present invention include epoxies, urethanes, polyesters, polyamides, polycarbonates, polyolefins, polyvinylchloride, polystyrenes, polyolefins, and (meth)acrylics. Mixtures of two or more organic polymer particles can be used as the abrasive medium, as well as particles comprising both inorganic and organic components. Preferably, the abrasives are selected or modified to be compatible with acidic media. In a preferred embodiment, the abrasive used in the copper removal CMP composition comprises a silica species, including, but not limited to, silica, acid-stable silica, silicon nitride, colloidal silica, and amorphous acid stable colloidal silica such as NexSil™ DP6190 (Nyacol Nano Technologies, Ashland, Mass., USA). More preferably, the abrasive used in the copper removal CMP composition of the present invention is DP6190. In a preferred embodiment, the abrasive agent in the copper removal CMP composition has a mean particle size in a range from about 10 nm to about 1000 nm, preferably about 20 nm to about 90 nm. Importantly, the abrasive is preferably substantially devoid of organometallic compounds.

The solvents employed in the copper removal CMP composition of the present invention may be single component solvents or multi-component solvents, depending on the specific application. In one embodiment of the invention, the solvent in the copper removal CMP composition includes water. In another embodiment, the solvent comprises water and an organic solvent such as straight-chained or branched C₁-C₆ alcohols, (e.g., methanol, ethanol, propanol, butanol), glycols, (e.g., ethylene glycol, propylene glycol), glycol ethers, amines, alkyl carbonates, (e.g., ethylene carbonate, propylene carbonate), glycerin, and combinations thereof. In yet another embodiment, the solvent comprises a water-alcohol solution. A wide variety of solvent types and specific solvent media can be employed in the general practice of the invention to provide a solvating/suspending medium in which the abrasive is dispersed and in which the other components are incorporated to provide a composition of appropriate character, e.g., of slurry form, for application to the platen of the CMP unit to provide a desired level of polishing of the copper on the wafer substrate.

The copper removal CMP composition of the present invention also includes at least one water soluble polymeric additive having available sites for hydrogen bonding, including carbonyls, alcohols, thiols, amines, etc., but do not cause particle flocculation or aggregation, i.e., the water soluble polymeric additive acts as an anti-flocculating agent. As defined herein, “anti-flocculating agent,” also known as a deflocculant, minimizes flocculation of the solid components of the composition. Flocculation processes including, but not limited to, depletion flocculation (entropy driven), electrostatic flocculation, capillary flocculation (the free energy of the particles is lower when the particles are in contact than when they are isolated in solution), other processes whereby interactive forces between the particles lead to aggregation, and combinations thereof, are preferably minimized using the anti-flocculating agent of the invention. In a preferred embodiment, the polymeric additive in copper removal CMP composition includes polyvinylpyrrolidone (PVP); any polymer made using the N-vinyl pyrrolidone monomer; polyacrylic acid esters and analogoues of polyacrylic acid esters; polyaminoacids such as polyalanine, polyleucine, polyglycine, etc.; polyamidohydroxyurethanes; polylactones; polyacrylamides; and combinations thereof. Preferably, the molecular weight of the polymeric additive is in a range from about 200 MW to about 500,000 MW, more preferably about 500 MW to about 100,000 MW, even more preferably about 1,000 MW to about 10,000 MW, and most preferably about 1,000 MW to about 5,000 MW, where MW corresponds to molecular weight in grams per mole. Preferably, the polymeric additive(s) do not substantially deposit on the surface of the microelectronic device.

The copper removal CMP composition of the present invention also includes a passivating agent. The term passivating agent as used herein, is intended to mean any substance that reacts with the fresh copper surface and/or oxidized copper thin film to passivate the copper layer and prevent excessive etching of the copper surface during CMP. Preferably, the passivating agent in the copper removal composition of the invention may comprise one or more inhibitor components including for example, triazoles, such as 1,2,4-triazole (TAZ), or triazoles substituted with substituents such as C₁-C₈ alkyl, amino, thiol, mercapto, imino, carboxy and nitro groups, such as benzotriazole, tolyltriazole, 5-phenyl-benzotriazole, 5-nitro-benzotriazole, 3-amino-5-mercapto-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, and the like, as well as thiazoles, tetrazoles, imidazoles, oxazoles, indoles, phosphates, thiols, thiophenes, pyrazoles, oxadiazoles, thiadiazoles, thiophenes, thiolanes, triazines, pyrazolidines, pyridazines, pyrazines, tetrazines, phopholes, other phosphole derivatives, piperazines, piperidines, and azines such as 2-mercaptobenzimidazole (MBI), 2-mercaptobenzothiazole, 4-methyl-2-phenylimidazole, 2-mercaptothiazoline, 5-aminotetrazole, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, etc. Dicarboxylic acids such as oxalic acid, malonic acid, succinic acid, nitrilotriacetic acid, iminodiacetic acid, and combinations thereof are also useful passivating agents. Combinations of any of the enumerated passivating agents are also contemplated. Importantly, when present, the ratio of triazole compound to benzotriazole compound in the copper removal CMP formulation is most preferably less than 1:1 or greater than 100:1. Preferred passivating agents include triazoles and their derivatives. In a specific embodiment, the preferred passivating agent is 1,2,4-triazole (TAZ).

In another embodiment, the copper removal CMP composition is substantially devoid of polyethylene oxide, a polyoxyethylene alkyl ether, a polyoxypropylene alkyl ether, a polyoxyethylenepolyoxypropylene alkyl ether and a polyoxyalkylene addition polymer. In another embodiment, the copper removal CMP composition is substantially devoid of alkylamines or alkoxyalkylamines having 4 to 6 carbon atoms. In still another particularly preferred embodiment, the copper removal CMP slurry is substantially devoid of aliphatic carboxylic acids such as lauric acid, linolic acid, myristic acid, palmitic acid, stearic acid, oleic acid, sebacic acid, and dodecanedoic acid. In still another preferred embodiment the copper removal CMP composition is devoid of citric acid, titania, tetrazole and derivatives thereof, benzotriazole and derivatives thereof, imidazole and derivatives thereof, isothiazolin-3-one, anthranilic acid, phenol compounds, aromatic diamine compounds, organic phosphonates, and oxidized metal etchants such as organic acids, inorganic acids, esters of organic acids, ammonia and ammonium salts of organic and inorganic acids. As defined herein, “substantially devoid” corresponds to less than about 2 wt. % of the compounds, preferably less than about 1 wt. % of the compounds, even more preferably less than 0.5 wt. % of the compounds, and preferably 0 wt. % of the compounds, based on the total weight of said composition.

Depending on the desired results of the copper removal CMP planarization, the concentration of the passivating agent may be varied to adjust the removal rate of copper without compromising the planarization efficiency.

The copper removal CMP composition of the present invention may also include a rheology agent, which serves to increase selectivity between copper and liner without significantly affecting the copper removal rate. Rheology is the study of change in form and flow of matter, and embraces elasticity, viscosity and plasticity (see, e.g. More Solutions to Sticky Problems, Brookfield Engineer Labs, Inc., P. 13, whose contents are herein incorporated by reference). Viscosity is a measure of internal friction in a fluid, caused by intermolecular attraction, which makes the fluid resist a tendency to flow.

The addition of a rheology agent to the copper removal CMP composition (slurry) of the present invention provides a means by which to modify the slurry's viscosity and laminar fluid flow, which encompasses the movement of one layer of the slurry past another, with a reduced transfer of matter between layers. Rheology agents in CMP slurries, such as those of the present invention, can be used to control dishing and erosion phenomena during planarization of sub-micron features.

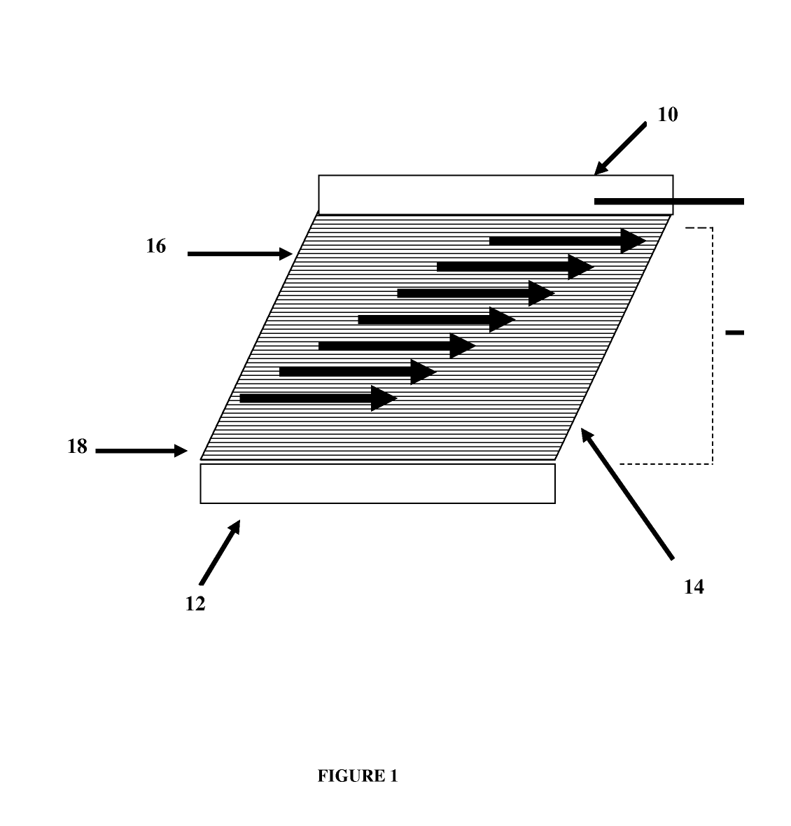

For example, FIG. 1 shows a depiction of laminar flow consistent with the meaning of the term as used herein. When a fluid, 14, such as the copper removal CMP composition of the present invention, is bound by two opposing plates, whereby one plate 10, moves while the second plate 12, remains stationary, it is found that there is a layer or lamina of fluid (slurry) 16, which moves with the plate, and a layer closest to the stationary plate which remains essentially stationary 18. The fluid or slurry tends to move in layers with each layer having a successively higher speed that creates a gradient of velocity as you move from the stationary to the moving plate. The gradient of velocity, also referred to as shear rate or rate of strain, is defined as the velocity of the top layer 16, with respect to the thickness of the film 20.

A pseudoplastic rheology agent introduces a flow behavior in which the viscosity of the slurry decreases as shear rate increases. During a CMP process, shear rate is highest at elevated topography (protuberances and asperities), allowing for greater material removal through increased abrasive particle momentum and mechanical polishing. And, reactants are provided more readily by means of higher fluid flow to the low viscosity areas near the asperities. In the vias and line trenches, where the shear rate is lower, a localized higher viscosity reduces fluid velocities. Lower fluid velocities help to maintain the passivation layer by reducing reactant transport and mechanical abrasion caused by turbulent mixing.

A rheology agent that increases the viscosity and laminar flow advantageously decreases the vertical flow of the slurry. In terms of polishing, this causes abrasive particles to move almost exclusively in the direction of the flow plane of the lamina between the wafer surface and the polishing pad.

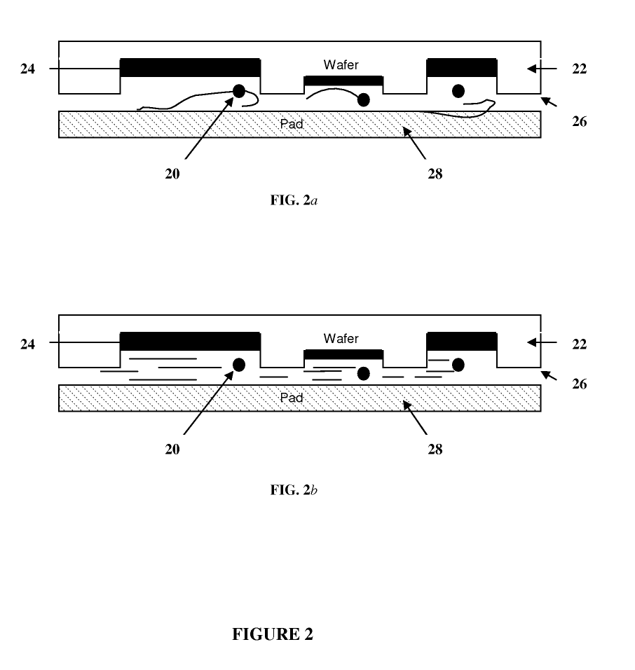

FIGS. 2a and 2b illustrate one effect of a rheology agent on laminar flow in a CMP process. In FIG. 2a, slurry-abrasive particles 20, flow freely in a three dimensional space between wafer 22, which includes copper features 24 and liner material 26, and a polishing pad 28. FIG. 2b shows the CMP process as in FIG. 2a, modified by addition of a rheology agent to the CMP slurry. Abrasive particles 20, become constrained in the flow plane (laminas) between wafer 22 and pad 28, thereby reducing wear to the copper features, by improving selectivity between copper 24 and liner 26, without significantly reducing the overall copper removal rate.

Preferably, the rheology agent used in the copper removal CMP composition of the present invention is compatible and stable when combined with other components in the slurry. Moreover, the rheology agent should be stable in a particular pH range and with a particular oxidizer. Preferred rheology agents are soluble in the active slurry components and non-reactive with the wafer surface chemistry. Useful rheology agents include, but are not limited to, cross-linked acrylic polymers and Water Soluble Polymers (WSPs). More particularly, useful rheology agents include Noveon's Carbopol® series of polymers (Cleveland, Ohio), modified cellulose derivatives, cellulose ethers, starch derivatives, pectin derivatives, polyacylamides, aqueous dispersions thereof, and combinations thereof. In a preferred embodiment, the rheology agent most useful in the present invention is selected from the group consisting of hydroxypropylcellullose, hydroxyethylcellulose, both available commercially from Aqualon (Wilmington, Del.), and carboxymethylcellulose. In a preferred embodiment, the rheology agent used in the present invention is hydroxypropylcellulose having a molecular weight in the range of 50,000 to 1,200,000 MW, preferably about 300,000 to about 1,000,000 MW.

Rheology agents tend to be polymeric and therefore molecular weight requirements differ depending on the type of rheology agent. For a class of water soluble polymers, such as those within the scope of the present invention, molecular weights greater than 50,000 are preferred. Preferably, the rheology agent increases the viscosity of the copper removal CMP composition to between 1.5 cSt (1.5 cP) and 50 cSt (52 cP) at 25° C. and more preferably to a range that is between 3.0 cSt to 5.0 cSt (3.1 cP to 5.2 cP).

The polymeric additive is a preferred component when the abrasive material comprises a metal oxide abrasive containing hydroxyl groups which are capable of hydrogen bonding with rheology agents when both abrasive and rheology agent(s) are present. It was discovered that silica abrasives would flocculate and precipitate out of a slurry including a rheology agent containing functional groups capable of hydrogen bonding in less than one hour. Surprisingly, it was discovered that the inclusion of the polymeric additive in the slurry including rheology agent and silica-containing abrasive minimized said flocculation for more than 2 weeks. Importantly, when the final composition includes abrasive, polymeric additive and rheology agent, the abrasive and the polymeric additive are preferably mixed first followed by the addition of the rheology agent.

In another embodiment of the present invention, the copper removal CMP composition may also comprise at least one oxidizing agent. The oxidizing agent of the copper removal CMP composition includes any substance which removes metal electrons and raises the atomic valence and includes, but is not limited to, hydrogen peroxide (H₂O₂), ferric nitrate (Fe(NO₃)₃), potassium iodate (KIO₃), potassium permanganate (KMnO₄), nitric acid (HNO₃), ammonium chlorite (NH₄ClO₂), ammonium chlorate (NH₄ClO₃), ammonium iodate (NH₄IO₃), ammonium perborate (NH₄BO₃), ammonium perchlorate (NH₄ClO₄), ammonium periodate (NH₄IO₃), tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄) IO₄), urea hydrogen peroxide ((CO(NH₂)₂)H₂O₂), and combinations thereof. The preferred oxidizing agent for the copper removal composition of the present invention is hydrogen peroxide.

Alternatively, the oxidizing agent may comprise an amine-N-oxide having the formula (R¹R²R³N→O), wherein R¹, R², and R³ are independently selected from the group consisting of hydrogen and straight-chained, branched, substituted or unsubstituted C₁-C₈ alkyl (e.g., methyl, ethyl, propyl, butyl, pentyl, hexyl, heptyl, and octyl). In another embodiment, the amine-N-oxide may have the formula (R¹R²N→O), where R¹ and R² may be the C₁-C₈ alkyl group as previously described and they are connected to form a ring. Specific examples of amine-N-oxides include but are not limited to 4-methylmorpholine-N-oxide (C₅H₁₁NO₂) and pyridine-N-oxide (C₅H₅NO).

In yet another embodiment of the present invention, the copper removal CMP composition may also comprise at least one chelating agent. The term chelating agent as used in the copper removal CMP composition of the present invention is intended to mean any substance that in the presence of an aqueous solution solubilizes or etches the oxidized copper material. Copper chelating agents and etchants useful in the present invention include but are not limited to inorganic acids and organic acids, amines and amino acids (e.g., glycine, alanine, citric acid, acetic acid, maleic acid, oxalic acid, malonic acid, phthalic acid, and succinic acid), nitrilotriacetic acid, iminodiacetic acid, ethylenediamine, cyclohexyl 1,2-diamine tetraacetic acid (CDTA), and ethylene diamine tetraacetic acid (EDTA), and combinations thereof. Preferably, the chelating agent used in the present invention is glycine.

Acids and bases may be optionally employed for pH adjustment in the copper removal CMP composition of the invention. As used herein, the terms “buffering agent” and “pH adjusting agent” refers to any of the acids or bases that may be optionally employed for pH adjustment in the copper removal CMP composition of the present invention. Illustrative acids include, for example, but are not limited to, formic acid, acetic acid, propanoic acid, butanoic acid, pentanoic acid, isovaleric acid, hexanoic acid, heptanoic acid, octanoic acid, nonanoic acid, lactic acid, hydrochloric acid, nitric acid, sulfuric acid, hydrofluoric acid, malic acid, fumaric acid, malonic acid, glutaric acid, glycolic acid, salicylic acid, 1,2,3-benzenetricarboxylic acid, tartaric acid, gluconic acid, citric acid, phthalic acid, pyrocatechoic acid, pyrogallol carboxylic acid, gallic acid, tannic acid, and mixtures including two or more acids of the foregoing or other types. Illustrative bases include, by way of example, potassium hydroxide, ammonium hydroxide and tetramethylammonium hydroxide (TMAH), tetraethylammonium hydroxide, trimethyl hydroxyethylammonium hydroxide, methyl tri(hydroxyethyl) ammonium hydroxide, tetra(hydroxyethyl)ammonium hydroxide, and benzyl trimethylammonium hydroxide. Preferably, the base is KOH.

It is also within the scope of the invention that other agents, such as amines, surfactants, defoaming agents and/or antimicrobial/biocide agents may also be a component of the copper removal CMP composition. Amines, when present, can be of any suitable type, including, by way of example, hydroxylamine, monoethanolamine, diethanolamine, triethanolamine, diethyleneglycolamine, N-hydroxyethylpiperazine, N-methylethanolamine, N,N-dimethylethanolamine, N-ethlethanolamine, N,N-diethlethanolamine, propanolamine, N,N-dimethylpropanolamine, N-ethylpropanolamine, N,N-diethylpropanolamine, 4-(2-hydroxyethyl)morpholine, aminoethylpiperazine, and mixtures including two or more of the foregoing or other amine species. Surfactants, when optionally employed in the CMP compositions of the present invention can be of any suitable type, including non-ionic, anionic, cationic, and amphoteric surfactants, and polyelectrolytes including, but not limited to, salts of organic acids, alkane sulfates (e.g., sodium dodecyl sulfate), alkane sulfonates, substituted amine salts (e.g., cetylpyridium bromide), betaines, polyacrylic acid, polyvinyl pyrrolidone, polyethyleneinine, and esters of anhydrosorbitols, such as those commercially available under the trademarks Tween® and Span®, as well as mixtures including two or more of the foregoing or other surfactant species. Defoaming agents contemplated include polymer-based, silicone-free, oil-free defoamers such as TD 1525 (Defoamer.com™, Geneva, Ill., USA). Biocides contemplated herein include 2-bromo-2-nitropropane-1,3-diol (bronopol).

In one embodiment of this aspect of the invention, the copper removal composition includes silica, triazole and/or derivatives thereof, any polymer including the N-vinyl pyrrolidone monomer, and water.

In a preferred embodiment, the copper removal composition comprises, consists of, or consists essentially of silica, TAZ, PVP and water. In another preferred embodiment, the copper removal composition comprises, consists of, or consists essentially of silica, TAZ, PVP, glycine and water. In yet another preferred embodiment, the copper removal composition comprises, consists of, or consists essentially of silica, TAZ, PVP, glycine, HPC, water, optionally buffering agent, optionally biocide and optionally defoamer. In still another preferred embodiment, the copper removal composition comprises, consists of, or consists essentially of silica, TAZ, PVP, glycine, HPC, H₂O₂, water, optionally buffering agent, optionally biocide and optionally defoamer.

A particularly preferred embodiment of the concentrate of the copper removal composition of the present invention comprises the following components present in the stated weight percents, based on the total weight of the composition:

| Component | Concentrate % by weight | Diluted % by weight |
|---|---|---|
| Glycine | About 1 to about 20% | About 2.5 to about 4.5% |
| 1,2,4-triazole (TAZ) | About 0.1 to about 3% | About 0.35 to about 0.55% |
| Polyvinylpyrrolidone (PVP) | About 0.01 to about 2% | About 0.03 to about 0.35% |
| DP6190 (silica) | About 0.1 to about 25% | About 0.5 to about 1.5% |
| KOH | About 0 to about 1% | About 0 to about 1% |
| Hydroxypropylcellulose (HPC) | About 0.01 to about 1% | About 0.05 to about 0.2% |
| Hydrogen Peroxide | About 0 to about 10% | About 0 to about 10% |
| defoaming agent | About 0.01 to about 1 | About 0.01 to about 1 |
| biocide | About 0.001 to about 0.5 | About 0.001 to about 0.5 |
| Water | About 75 to about 95% | About 75 to about 95% |

and preferred formulation A, without hydrogen peroxide:

| Component | without H₂O₂/wt % |
|---|---|
| Glycine | about 3.6 |
| 1,2,4-triazole (TAZ) | about 0.48 |
| Polyvinylpyrrolidone (PVP) | about 0.06 |
| DP6190 (silica) | about 1.2 |
| KOH | 0 to about 1 |
| Hydroxypropylcellulose (HPC) | about 0.12 |
| water | about 92.54 to about 94.53 |
| TD 1525 | about 0.01 to about 0.5 |
| bronopol | about 0.001 to about 0.5 |
| pH | about 5 |

The amount of hydrogen peroxide present in concentrate A may be in a range from about 0.1 wt. % to about 10 wt. %, preferably about 2 wt. % to about 5 wt. %, based on the total weight of the composition.

Preferred formulation B, with 2.8 wt. % H₂O₂ includes:

| Component | with H₂O₂/wt % |
|---|---|
| Glycine | about 0.74 |
| 1,2,4-triazole (TAZ) | about 0.11 |
| Polyvinylpyrrolidone (PVP) | about 0.014 |
| DP6190 (silica) | about 0.28 |
| H₂O₂ | about 2.8 |
| KOH | about 0.002 |
| Hydroxypropylcellulose (HPC) | about 0.028 |
| water | about 95.03 to about 96.02 |
| TD 1525 | about 0.001 to about 0.5 |
| bronopol | about 0.001 to about 0.5 |
| pH | about 5 |

and preferred formulation C, with 2.3 wt. % H₂O₂ includes:

| Component | with H₂O₂/wt % |
|---|---|
| Glycine | about 0.74 |
| 1,2,4-triazole (TAZ) | about 0.11 |
| Polyvinylpyrrolidone (PVP) | about 0.056 |
| DP6190 (silica) | about 0.28 |
| H₂O₂ | about 2.3 |
| KOH | about 0.002 |
| Hydroxypropylcellulose (HPC) | about 0.028 |
| water | about 95.48 to about 96.48 |
| TD 1525 | about 0.001 to about 0.5 |
| bronopol | about 0.001 to about 0.5 |
| pH | about 5 |

The copper removal composition described herein, comprising at least one abrasive, at least one solvent, at least one passivating agent, at least one rheology agent, and at least one polymeric additive, wherein the abrasive comprises silica, eliminates flocculation of the abrasive particles and shows improved overpolish robustness in comparison to copper removal compositions devoid of the polymeric additive.

As disclosed herein polymeric additives are a preferred component when the abrasive composition comprises a metal oxide abrasive containing hydroxyl groups and additives that cause bridging flocculation including, but not limited to, glycols, glycerol, other cellulosics, polyethylene glycol (PEG) and polyethylene oxide (PEO). Accordingly, the inclusion of a polymeric additive of the invention to a composition including a metal oxide abrasive containing hydroxyl groups and additives that cause bridging flocculation is not limited to a CMP composition but may also include home cleaning products, toothpastes, casting slips, inks, paints, and pigment systems, to name a few.

In another aspect, the copper removal CMP composition may be diluted using a diluent, wherein the concentrate described herein may be diluted with a diluent in a range from about 1:1 to about 10:1 diluent to concentrate, preferably about 3:1 to about 6:1, more preferably about 4:1 to about 4.5:1, and most preferably about 4.3:1. The diluent may include at least one solvent, at least one oxidizing agent, or combinations thereof, as described herein, preferably the same solvent(s) used to formulate the copper removal CMP concentrate. For example, the diluent may include water and hydrogen peroxide. Dilution may be performed at the manufacturer, manually or automatically upstream of the CMP tool, manually or automatically at the point of use. It should be appreciated that dilution may be effectuated prior to and/or during polishing.

The barrier layer CMP composition generally includes at least one oxidizing agent, at least one passivating agent, at least one barrier layer removal enhancer, at least one selectivity additive, at least one abrasive, at least one solvent, and optionally at least one pH adjusting agent, present in the following ranges, based on the total weight of the composition:

| component | % by weight |
|---|---|
| oxidizing agent(s) | about 0% to about 20.0% |
| passivating agent(s) | about 0.01% to about 10.0% |
| Barrier layer removal enhancer(s) | about 0.01% to about 10.0% |
| selectivity additive(s) | about 0.001% to about 10.0% |
| abrasive(s) | about 1.0% to about 30.0% |
| solvent(s) | about 20% to about 98.98% |
| pH adjustment agent(s) | 0 to about 1% |

The barrier layer composition was previously described in PCT Patent Application No. PCT/US06/22037, filed on Jun. 6, 2006, which claims priority of U.S. Provisional Patent Application No. 60/687,821, filed Jun. 6, 2005, both of which are incorporated by reference herein in their entireties.

The pH of the barrier layer CMP composition is generally in a range from about 2 to about 12, preferably in a range from about 2 to about 5. The range of weight percent ratios for barrier layer remover enhancer(s) relative to passivating agent(s) is about 0.1:1 to about 10:1, preferably about 0.5:1 to about 5:1, and most preferably about 1:1 to about 2:1; the range of weight percent ratios for selectivity additive(s) relative to passivating agent(s) is about 0.01:1 to about 5:1, preferably about 0.1:1 to about 3:1, and most preferably about 0.2:1 to about 1:1; the range of weight percent ratios for abrasive(s) relative to passivating agent(s) is about 1:1 to about 100:1, preferably about 25:1 to about 75:1, most preferably about 40:1 to about 60:1; and the range of weight percent ratios for oxidizing agent(s) relative to passivating agent(s) is about 0.1:1 to about 10:1, preferably about 0.25:1 to about 3:1, and most preferably about 0.5:1 to about 1:1.

The barrier removal CMP formulation may comprise, consist of, or consist essentially of at least one oxidizing agent, at least one passivating agent, at least one barrier layer removal enhancer, at least one selectivity additive, at least one abrasive material, at least one solvent, and optionally at least one pH adjusting agent. In general, the specific proportions and amounts of oxidizing agent(s), passivating agent(s), barrier layer removal enhancer(s), selectively additive(s), abrasive material(s), solvent(s), and optional pH adjusting agent(s), in relation to each other, may be suitably varied to provide the desired removal action of the barrier layer material from the microelectronic device substrate having same thereon, as readily determinable within the skill of the art without undue effort. Importantly, the barrier removal CMP formulation is devoid of persulfate and phosphorous acid and phosphoric acid and/or a salt thereof.

The barrier removal CMP polishing formulation may include the following components present in the following ranges, based on the total weight of the composition:

| component | % by weight |
|---|---|
| oxidizing agent(s) | about 0.05% to about 1.5% |
| passivating agent(s) | About 0.1% to 1.0% |
| barrier layer removal enhancer(s) | about 0.1% to about 0.5% |
| selectivity additive(s) | about 0.05% to about 1.0% |
| abrasive(s) | about 5.0% to about 15.0% |
| solvent(s) | about 86.1% to about 94.7% |
| pH adjustment agent(s) | about 0.001% to about 0.5% |
| pH | about 2 to about 5 |

A preferred barrier removal CMP composition comprises a formulation represented by Formulation D:

Formulation D

| 1,2,4-triazole | 0.2 | wt. % |
|---|---|---|
| phthalic acid | 0.3 | wt. % |
| polyacrylic acid (2,000 MW) | 0.1 | wt. % |
| acid-stabilized silica | 10 | wt. % |
| H₂O₂ | 0.18 | wt. % |
| KOH or HNO₃ | 0.06-0.09 wt. % | |
| water | balance | |
| pH about 3.5 | | |

The abrasive contemplated for the barrier removal CMP composition preferably include those enumerated herein for the copper removal CMP composition. The abrasive in the copper removal CMP composition and barrier removal CMP composition may be the same as, or different from one another. A preferred abrasive component of the barrier removal CMP composition is also acid-stable silica. The preferred diameter of said abrasive is in a range from about 10 nm to about 1000 nm, preferably about 20 nm to about 90 nm.

The oxidizing agents that may be used within a barrier removal CMP composition include those enumerated herein for the copper removal CMP composition. The oxidizing agents in the copper removal CMP composition and barrier removal CMP composition may be the same as, or different from one another. In a preferred formulation, the barrier removal CMP composition comprises hydrogen peroxide as an oxidizing agent.

The passivating agents contemplated for the barrier removal CMP composition preferably include those enumerated herein for the copper removal CMP composition. Namely, the passivating agents in the copper removal and barrier removal CMP compositions may be the same as, or different from one another. In a preferred formulation, both the copper removal and barrier removal CMP compositions employ the same passivating agent. The passivating agent should not have a measurable effect on the zeta potential of the abrasive in the preferred pH regime. Preferably, 1,2,4-triazole (TAZ) is the passivating agent used in the barrier removal CMP composition.

The barrier layer removal enhancer is added to increase the rate of removal of barrier layer material during the CMP polishing process. Preferably, the removal enhancer in the barrier removal CMP composition may comprise one or more barrier layer removal components, for example, aromatic carboxylic acids, including but not limited to, benzoic acid, phthalic acid, salicylic acid, substituted benzoic acid, phenylalkanoic acid (where the alkanoic acid may be any straight-chained or branched C₁ to C₆ carboxylic acid) and other aromatic carboxylic acids. Preferably, the barrier layer removal enhancer of the barrier removal CMP composition is phthalic acid.

The selectivity additive is added to reduce the removal rate of copper during the second step of the CMP polishing process to control selectivity. In a preferred formulation, some copper is removed (at a nonzero rate) to prevent residual copper defects. Preferably, the selectivity additive in the barrier removal CMP composition may comprise one or more selectively components including for example, poly(acrylic acid), anionic surfactants, and other polyelectrolytes. Preferably, the selectivity additive is poly(acrylic acid) (PAA) with a molecular weight in the range from about 400 MW to about 8,000,000 MW.

A preferred barrier removal CMP composition includes acid-stable silica, 1,2,4-triazole, H₂O₂, phthalic acid and PAA in an aqueous solution at a pH of about 3.5.

The solvent(s) contemplated for the barrier removal CMP composition preferably include those enumerated herein for the copper removal CMP composition. Namely, the solvent(s) in the copper removal and barrier removal CMP compositions may be the same as, or different from one another. In a preferred formulation, both the copper removal and barrier removal CMP compositions employ the same solvent(s), preferably including water.

Acids and bases may be optionally employed for pH adjustment in the barrier removal CMP composition. The acid(s) and base(s) for pH adjustment contemplated for the barrier removal CMP composition preferably include those enumerated herein for the copper removal CMP composition. Namely, the acid(s) and base(s) in the copper removal and barrier removal CMP compositions may be the same as, or different from one another.

In addition, barrier removal CMP formulations may further comprise additional components including, but not limited to, defoaming agents, biocides (e.g., antimicrobials), rheology agents, polymeric additives, and surfactants, as described above for the copper removal CMP composition. In a particularly preferred embodiment, the barrier removal CMP formulations further include at least one rheology agent and at least one polymeric additive.

Similar to the copper removal CMP composition, the barrier removal CMP composition may be provided as a concentrate that may be diluted before and/or at the point of use, as described hereinabove.

The CMP formulations of the present invention may be provided as a single package formulation or a multi-part formulation that is mixed at the point of use or in a storage tank upstream of the tool. The advantage of a multi-part formulation resides in its extended shelf life relative to single-package formulations. A single package formulation is more susceptible to decomposition and change of its properties over time, in relation to a multi-part formulation, due to the presence of the oxidizer in the single-package CMP formulation. The concentrations of the single-package formulation or the individual packages of the multi-part formulations may be widely varied in specific multiples, i.e., more dilute or more concentrated, in the broad practice of the invention, and it will be appreciated that the CMP formulations of the invention can variously and alternatively comprise, consist or consist essentially of any combination of ingredients consistent with the disclosure herein. Importantly, the multi-part formulation enables higher component concentrations than is possible in a single package system. These higher concentrations reduce manufacturing, shipping and storage costs for the manufacturer and concomitantly reduces the cost of ownership for the end user.

Accordingly, another aspect of the invention relates to a kit including, in one or more containers, the components adapted to form the formulations of the invention as described hereinabove. The containers of the kit must be suitable for storing and shipping said removal composition components, for example, NOWPak® containers (Advanced Technology Materials, Inc., Danbury, Conn., USA). The one or more containers which contain the components of the removal composition preferably include means for bringing the components in said one or more containers in fluid communication for blending and dispense. For example, referring to the NOWPak® containers, gas pressure may be applied to the outside of a liner in said one or more containers to cause at least a portion of the contents of the liner to be discharged and hence enable fluid communication for blending and dispense. Alternatively, gas pressure may be applied to the head space of a conventional pressurizable container or a pump may be used to enable fluid communication. In addition, the system preferably includes a dispensing port for dispensing the blended removal composition to a process tool. The solution to be stored in NOWPak® or similar containers may optionally be degassed or purged with an inert gas in order to reduce oxidative corrosion of polysilicon and other potentially sensitive materials.

Substantially chemically inert, impurity-free, flexible and resilient polymeric film materials, such as high density polyethylene, are preferably used to fabricate the liners for said one or more containers. Desirable liner materials are processed without requiring co-extrusion or barrier layers, and without any pigments, UV inhibitors, or processing agents that may adversely affect the purity requirements for components to be disposed in the liner. A listing of desirable liner materials include films comprising virgin (additive-free) polyethylene, virgin polytetrafluoroethylene (PTFE), polypropylene, polyurethane, polyvinylidene chloride, polyvinylchloride, polyacetal, polystyrene, polyacrylonitrile, polybutylene, and so on. Preferred thicknesses of such liner materials are in a range from about 5 mils (0.005 inch) to about 30 mils (0.030 inch), as for example a thickness of 20 mils (0.020 inch).

Regarding the containers for the kits of the invention and systems for delivering same to the table, the disclosures of the following patents and patent applications are hereby incorporated herein by reference in their respective entireties: U.S. Pat. No. 7,188,644 entitled “APPARATUS AND METHOD FOR MINIMIZING THE GENERATION OF PARTICLES IN ULTRAPURE LIQUIDS;” U.S. Pat. No. 6,698,619 entitled “RETURNABLE AND REUSABLE, BAG-IN-DRUM FLUID STORAGE AND DISPENSING CONTAINER SYSTEM;” and U.S. Provisional Patent Application No. 60/916,966 entitled “SYSTEMS AND METHODS FOR MATERIAL BLENDING AND DISTRIBUTION” filed on May 9, 2007 in the name of John E. Q. Hughes.

As described above, the CMP formulations of the present invention may be delivered from a single package to the polishing table for use in a CMP process. Alternatively, each single ingredient of the CMP formulation may be individually delivered to the polishing table for combination at or before the table, to constitute the CMP formulation for use. In a preferred embodiment, the CMP formulation is formulated as a multi-part formulation in which a number of components of the CMP formulation are in a first container, a number of components of the CMP formulation are in a second container, etc., for combination at or before the tool, optionally with components provided by the user, to constitute the CMP formulation for use. For example, the first part comprises, for example, at least one abrasive, at least one solvent, at least one polymeric additive and at least one passivating agent, and a second part comprises at least one oxidizing agent. The multi-part formulation embodiments disclosed herein are not meant to be limiting in any way and may include alternative combinations. In all of these various embodiments, Part A, Part B, and Part C (when present) are mixed with Part D, which includes the oxidizing agent (which may be provided by the manufacturer or alternatively is provided by the user or supplied by the manufacturing/processing facility via a material supply feed), and optionally Part E, which consists of water, preferably deionized water. The mixing of ingredients or parts to form the final formulation may occur at the point of use (e.g., mixing at the polishing table, polishing belt or the like) or in an appropriate mixing/contacting zone, region, area, chamber, container or the like preceding the point of use or shortly before reaching the polishing table, or at the CMP formulation manufacturer and/or supplier. It should be appreciated that in addition to the Part D and optional Part E, pH adjusting agent(s) may be added to achieve the preferred final pH.

For example, preferred component combinations for the copper removal CMP composition are as follows:

| | | | Part C |
|---|---|---|---|
| Kit | Part A | Part B | (dry components) |
| 1 | (up to 20× concentration) | (up to 50× concentration) | — |
| | abrasive | water | |
| | water | chelator | |
| | polymeric stabilizing agent | passivating agent | |
| | biocide | biocide | |
| | | defoamer | |
| | | rheology agent | |
| 2 | (up to 20× concentration) | (up to 50× concentration) | — |
| | abrasive | water | |
| | water | chelator | |
| | polymeric stabilizer | passivating agent | |
| | biocide | biocide | |
| | defoamer | | |
| | rheology agent | | |
| 3 | (up to 10× concentration) | (up to 50× concentration) | — |
| | abrasive | water | |
| | water | chelator | |
| | polymeric stabilizer | biocide | |
| | biocide | | |
| | defoamer | | |
| | passivating agent | | |
| | rheology agent | | |
| 4 | (up to 20× concentration) | (up to 50× concentration) | — |
| | abrasive | water | |
| | water | chelator | |
| | polymeric stabilizer | passivating agent | |
| | biocide | biocide | |
| | defoamer | rheology agent | |
| 5 | (up to 10× concentration) | (up to 50× concentration) | — |
| | abrasive | water | |
| | water | chelator | |
| | polymeric stabilizer | biocide | |
| | biocide | rheology agent | |
| | defoamer | | |
| | inhibitor | | |
| 6 | (up to 20× concentration) | DI water | passivating agent |
| | abrasive | | chelator |
| | water | | |
| | polymeric stabilizer | | |
| | biocide | | |
| | defoamer | | |
| | rheology agent | | |
| 7 | (up to 10× concentration) | DI water | chelator |
| | abrasive | | |
| | water | | |
| | polymeric stabilizer | | |
| | biocide | | |
| | defoamer | | |
| | passivating agent | | |
| | rheology agent | | |
| 8 | (up to 20× concentration) | (up to 50× concentration) | |
| | abrasive | rheology agent | |
| | passivating agent | polymeric stabilizer | |
| | chelating agent | passivating agent | |
| | biocide | biocide | |
| | water | defoamer | |
| | | water | |

For example, referring to kit 8, a predetermined amount of Part A, Part B, Part D and Part E may be combined at the table to produce Formulation A for the soft landing CMP process. In a particularly preferred embodiment, Part A comprises, consists of, or consists essentially of abrasive, passivating agent, chelating agent, water and optionally biocide and Part B comprises, consists of, or consists essentially of rheology agent, polymeric stabilizer, passivating agent, water, optionally biocide and optionally defoamer, wherein both Part A and Part B are substantially devoid of oxidizing agent. In an even more preferred embodiment, Part A comprises, consists of, or consists essentially of silica, TAZ, glycine, water and optionally biocide and Part B comprises, consists of, or consists essentially of HPC, PVP, TAZ, water, optionally biocide and optionally defoamer, wherein both Part A and Part B are substantially devoid of oxidizing agent.

As should be appreciated, the individual parts of the formulations described herein may be provided at concentrations in a range from about 50 times to about 2 times greater than that preferred during polishing. Accordingly, the concentrated formulation parts may be diluted with the appropriate solvent and/or other components at the point of use (e.g., mixing at the polishing table, polishing belt or the like) or in an appropriate container shortly before reaching the polishing table. Preferably, the diluting solvent comprises the solvent of the specific CMP slurry composition. Importantly, dilution may be effectuated before and/or during the polish by direct addition of the solvent to the platen.

Similarly, the barrier removal CMP composition may be made by the mixing of ingredients or parts to form the final formulation at the point of use (e.g., mixing at the polishing table, polishing belt or the like), in an appropriate container shortly before reaching the polishing table, or at the CMP formulation manufacturer and/or supplier.

Another aspect of the present invention provides for a method of polishing a microelectronic device wafer substrate on at least one platen. The method comprises contacting the device wafer for sufficient time and under at least one copper removal CMP condition with at least one copper removal CMP composition to substantially remove the copper from the wafer and expose the barrier material, followed by contacting the device wafer for sufficient time and under barrier removal CMP conditions with a barrier removal CMP composition to substantially remove the barrier layer from the wafer and expose the underlying dielectric material.

In one embodiment, the CMP process corresponds to an in situ transition of the copper removal CMP polishing composition into a barrier removal CMP polishing composition on a single platen, i.e., without transference of the microelectronic device substrate to a second platen for the barrier removal CMP polishing step. This is possible because of the substantial compatibility of the copper removal and barrier landing CMP formulations and the effectiveness of the pad cleaning step. It should be appreciated that the in situ transition may correspond to the bulk copper to soft landing to barrier removal transition all on a single platen or the soft landing to barrier removal transition on a single platen.

In practice, when the in situ, one platen, process includes the bulk removal copper process, a bulk copper removal CMP composition may be delivered to the platen for bulk copper removal. The copper removal composition of the invention may be used for bulk copper removal or alternatively, a commercial or proprietary bulk copper removal composition may be used. The processing conditions of the bulk copper removal sub-step include a platen pad downforce in a range from about 0.1 psi to about 7 psi, preferably about 3 psi to about 7 psi.

Following the removal of the bulk copper, the “soft landing” process is effectuated. If the copper removal CMP composition of the invention is used as the bulk copper removal composition, the processing conditions may be altered and/or the copper removal CMP composition diluted for the soft landing process. If a commercial or proprietary bulk copper removal composition is used as the bulk copper removal composition, the copper removal CMP composition described herein may be delivered to the platen for soft landing processing. Processing conditions of the “soft landing” sub-step include a platen pad downforce in a range from about 0.1 psi to about 7 psi, preferably less than or equal to 3 psi. Preferably the downforce for soft landing using the copper removal composition of the invention is about 1 psi. The “soft landing” sub-step is ceased when the endpoint is reached, as readily determinable by one skilled in the art. Endpoint methods include, but are not limited to, friction or torque measurements, eddy current thickness measurements, film reflectance measurements, imaging analysis, and chemical sensing. The processing conditions of the over-polish sub-step include a platen pad downforce in a range from about 0.1 psi to about 4 psi, preferably less than or equal to 3 psi. The length of time of the over-polish sub-step is readily determinable by those skilled in the art. In a preferred embodiment, the downforce of the bulk copper removal is greater than the downforce of the “soft landing” which is equal to or greater than the downforce of the over-polish.

Alternatively or additionally, it should be appreciated that the soft-landing and over-polishing steps may be controlled by varying the concentration of the components in the composition. For example, the copper removal CMP composition may be further diluted for the over-polishing process.

The copper removal rate can be adjusted over a substantial range as determined by those skilled in the art. The preferred copper to tantalum selectivity during the copper removal CMP step may be in a range from about 100:1 to about 10,000:1, preferably about 400:1 to about 1000:1.

In one embodiment, the platen and microelectronic device substrate may be rinsed with a solvent such as water or a pad cleaning agent following completion of the bulk copper CMP polishing step and/or soft-landing CMP polishing step. Preferably, the solvent is the same as that used in the copper removal, e.g., soft landing, and/or barrier removal CMP formulations described herein, e.g., water. The pad cleaning chemistry is preferably a solution of a carboxylic acid and its ammonium salt, such as the commercial product LP-12 (ATMI, Danbury, Conn., USA), more preferably, a 10:1 dilution (with water) of LP-12. In yet another embodiment, following completion of the copper removal, i.e., soft-landing, the polishing pad is rinsed with the barrier removal CMP composition.

Thereafter, the barrier removal CMP composition is delivered to the platen for the barrier removal CMP polishing step. The processing conditions of barrier removal CMP polishing step include a downforce in a range from about 0.1 psi to about 7 psi, preferably about 0.5 psi to about 4 psi.

The barrier removal CMP composition may be tuned to alter the removal rates of copper relative to barrier layer material relative to dielectric stack. Specifically, the selectivities may be tuned by adjustment of chemical composition, oxidizer concentration, abrasive loading, downforce, and other processing parameters. Accordingly, the barrier removal CMP composition may be tuned for different integration requirements, as readily determinable by one skilled in the art. Preferably, the copper removal rate during the barrier removal step is in a range from about 100 Åmin⁻¹ to about 1,500 Åmin⁻¹, most preferably in a range from about 300 Åmin⁻¹ to about 1000 Åmin⁻¹. The preferred copper to tantalum selectivity and copper to dielectric selectivity during the second step may be in a range from about 10:1 to about 1:10, more preferably in the range from about 1:1 to 1:10. Specific targets are driven by process integration requirements.

Notably, when the processing is performed on a single platen, the concentration of the bulk copper CMP composition components are accounted for (if using a commercial or proprietary bulk copper CMP composition) when determining how much of the copper removal CMP composition components must be added to the platen pad, as readily determined by one skilled in the art. Further, the concentration of the copper removal CMP composition components are accounted for when determining how much of the barrier removal CMP composition components must be added to the platen pad, as readily determined by one skilled in the art.

In another embodiment, the CMP process may include the copper removal CMP polishing step at one or more platens using the one or more copper removal CMP composition(s) followed by the barrier removal CMP polishing step on a different platen using the barrier removal CMP composition. For example, bulk copper removal and soft landing may be effectuated on a single platen using (a) the copper removal composition described herein for both processes or (b) a commercial or proprietary bulk copper removal composition and the copper removal composition described herein, respectively, wherein the commercial or proprietary bulk copper removal composition and the copper removal composition are chemically compatible. Thereafter, the device wafer may be moved to a second platen for barrier removal using a barrier removal CMP composition. Alternatively, bulk copper removal may be effectuated on a first platen using a bulk copper removal composition (whether the copper removal composition described herein, a commercial bulk copper removal composition or a proprietary bulk copper removal composition), the device wafer may be moved to a second platen for soft landing processing using the copper removal CMP composition described herein, and the device wafer may be moved to a third platen for barrier removal processing using a barrier removal CMP composition. The preferred and example parameters of each are as described above.

Following completion of each step of the CMP process of this embodiment, the polished substrate may be removed from the platen prior to the next processing step. The polishing pad may be thoroughly cleaned prior to polishing of a substrate to prevent carryover of slurry. Preferably, the solvent is the same as that used in the copper removal and/or the barrier removal CMP compositions described herein, e.g., water. The pad cleaning chemistry is preferably a solution of a carboxylic acid and its ammonium salt, such as the commercial product LP-12 (ATMI, Danbury, Conn., USA), more preferably, a 10:1 dilution (with water) of LP-12.

In another aspect, the present invention relates to methods for supplying fluid-containing feed (process) materials to multiple fluid-utilizing process tools and/or processing stations by using common sources of different process materials (at least one source preferably being concentrated), using at least one dedicated blending manifold for each process tool and/or station, regulating supply of each process material to each blending manifold, and blending process materials in desired proportions in each blending manifold associated with a different process tool and/or processing station. Constituents disposed within a single process material container should be compatible with one another, without causing substantial chemical reaction, precipitation, or degradation. Although it is contemplated that different (e.g., concentrated) process materials as described herein will have different compositions, common constituents may be present in multi-constituent process materials supplied by different process material sources, if compatible with the desired end use application.

Blending process materials as required just prior to the point of use provides numerous benefits. It enables use of highly concentrated chemistries or materials that last longer than conventional pre-blended formulations. It enables process material compositions to be varied as a function of time during an uninterrupted material (e.g., semiconductor device) processing step. In performing planarization of delicate structures, variation of process material composition may be useful to achieve desired removal rates without applying high downforce from a polishing head on such structures. The ability to controllably vary process material composition further enables optimization of sequential multi-step processing operations to maximize throughput. For example, the method may include three processing steps P1-P3, which may be used to perform sequential bulk copper removal (P1), soft landing copper clearing (P2), and barrier removal (P3) processes, at the same platen or using multiple platens. On a wafer processing tool including sequential polishing stations P1, P2, and P3, optimization may include, for example, reducing P1, P2, or P3 time; reducing total P1, P2, and P3 time; reducing total P1 and P2 time; and balancing any of P1, P2, and P3 times.

Overall goals of this aspect of the invention are to shorten the individual processing times per process step and balance the station processing times with respect to each other. Algebraic balancing formulas for accomplishing such goals may be developed by one skilled in the art. Factors to be considered in trying to improve throughput of a polishing tool include, but are not limited to: type of polishing tool; chemical and mechanical properties of the polishing pad(s); type of material to be removed; amount of material to be removed and/or desired endpoint thickness profile; chemical and mechanical properties of the CMP formulation; and downforce exerted onto the wafer. Suitable selection and adjustment of the foregoing and other factors is within the skill of one having ordinary skilled in the art.

For example, in a typical CMP system that includes three sequential processing steps P1, P2, P3, a first P1 endpoint (“EP”) system monitors copper (Cu) thickness and generates an instruction to stop polishing upon detection of an endpoint criterion (e.g., predefined thickness at dashed line). Similarly, a second P2 EP system generates an instruction to stop polishing when it detects that Cu has been removed. Removal rate in the following discussion may be abbreviated as “RR.” Optimization may start with looking at the polishing time of P1, P2 and P3, wherein:

P1 time (t_{P1})=Bulk Cu Thickness/RR(Bulk)

P2 time (t_{P2})=Cu Thickness (Landing)/RR(Landing)

P3 time (t_{P3})=Barrier Thickness/RR(Barrier)

For example, if P1 time=60 seconds; P2 time=80 seconds; and P3 time=100 seconds, then P2 and P3 are bottlenecks and their polishing times should be balanced first. To balance P1 and P2 time, more Cu can be removed at P1.

In other words, the various steps of a multi-step sequential wafer planarization process are preferably optimized and/or algebraically balanced to improve tool utilization and process efficiency. The station with the longest total processing time determines and limits the tool throughput. As will be appreciated by one of ordinary skill in the art, any suitable combination of two or more process materials may be supplied to a blending manifold at desired flow rates and proportions, and the blended product supplied to a process (e.g., during uninterrupted process operation) to achieved the desired result with respect to a multi-step sequential or other process operation.

The following Examples are merely illustrative of the invention and are not intended to be limiting.

### EXAMPLE 1

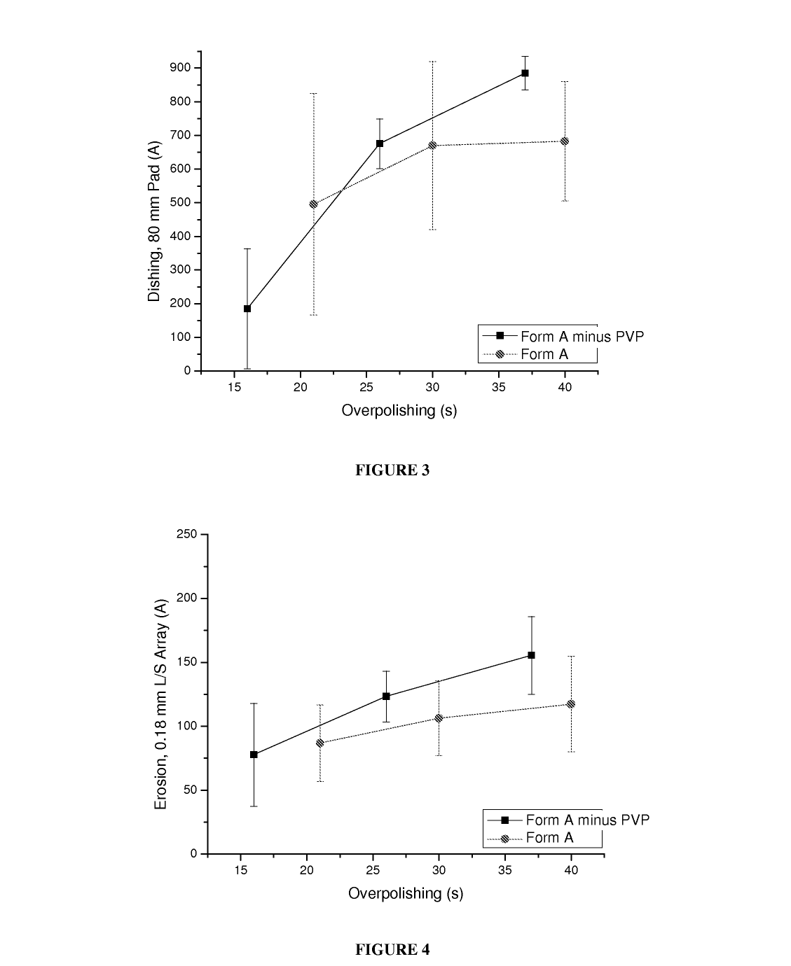

Copper dishing of a 80 μm bond pad (in Angstroms) and erosion of a 50% pattern density 0.18 μm L/S array (in Angstroms) as a function of overpolishing after the tool endpoint (in seconds) is shown in FIGS. 3 and 4, respectively, for polishing using formulation A and a variation of formulation A minus the polymeric agent PVP. A Mirra CMP Polisher (Applied Materials, Sunnyvale, Calif.) in overpolish at 1 psi membrane pressure, 0 psi inner tube pressure and 1 psi retaining ring pressure at 107/113 rpm carrier/platen rotating speed was used. It can be seen that the presence of the PVP (i.e., formulation A) in the slurry formulation reduces the rate of dishing and the overall dishing of the copper bond pad (see FIG. 3). In addition, the presence of PVP in the slurry formulation reduces the erosion of the array (see FIG. 4). Although not wishing to be bound by theory, it is hypothesized that the PVP passivates the colloidal silica surface making the silica amenable for use with rheological agents such as HPC and corrosion inhibitors that would otherwise flocculate the silica and result in increased dishing.

### EXAMPLE 2

A multi-part formulation of the composition of the invention may be provided as follows:

Part 1: abrasive and polymeric additive at a concentration 20× greater than that recommended for use during CMP polishing;
Part 2: the remaining ingredients at a concentration 5× greater than that recommended for use during CMP polishing;
Part 1 and Part II may be mixed with additional deionized water and oxidizing agent for delivery at the tool.

Alternatively, the multi-part formulation of the composition may be provided as follows:

Part 1: abrasive, polymeric additive, rheology agent, defoamer and biocide;
Part 2: the remaining ingredients as a dry mixture;

Part 2 may be dissolved by the end-user and Parts 1 and 2 mixed with additional deionized water and oxidizing agent for delivery to the tool.

Alternatively, the multi-part formulation of the copper removal composition may be provided as follows:

Part 1: abrasive, passivating agent, chelating agent, biocide, water
Part 2: rheology agent, polymeric additive, passivating agent, biocide, defoamer, wafer
Parts 1 and 2 may be mixed with additional water (preferably deionized) and oxidizing agent for delivery to the tool.

In a particularly preferred embodiment, the multi-part formulation of the soft-landing composition includes:

Part 1: silica (e.g., DP6190), 1,2,4-triazole, glycine, biocide and water
Part 2: hydroxypropylcellulose, polyvinylpyrrolidone, 1,2,4-triazole, biocide, defoamer and water.
Parts 1 and 2 may be mixed with additional water (preferably deionized) and oxidizing agent for delivery to the tool. It should be appreciated that in addition to the water and oxidizing agent, pH adjusting agent(s) may be added to achieve the preferred final pH.

### EXAMPLE 3

A stable formulation consisting of abrasive, polymeric additive and water was prepared as follows. 10 g of PVP was dissolved in 355 g of water. Thereafter, 645 g of DP6190 were added to the aqueous PVP solution. The resulting slurry contains 20 wt. % slurry and 1 wt. % PVP. After nearly 30 days, the slurry exhibited no sedimentation behavior, either as a clear band or sedimented particles at the bottom of the container. Moreover, the slurry did not gelatinize or change opacity. Notably, the addition of PVP directly into a solution consisting of DP6190 in water resulted in the formation of a gel.

### EXAMPLE 4

As described hereinabove, one aspect of the present invention relates to the process of blending materials in desired proportions in a blending manifold for delivery to a process tool and/or processing station. For example, concentrates may be formulated for the copper removal CMP process whereby the bulk copper removal composition and the copper removal composition described herein are readily blended for use from one and two concentrated formulations, respectively.

For example, assuming that the bulk copper removal composition includes 3 wt. % glycine, 0.05 wt. % TAZ, 1 wt. % acid-stabilized silica, and 5 wt. % H₂O₂, and the copper removal composition includes 3 wt. % glycine, 0.4 wt. % TAZ, 1 wt. % acid-stabilized silica, 0.1 wt. % HPC, and 0.2 wt. % PVP, the blending concentrates may include:

| Concentrate A1 | Concentrate B1 |
|---|---|
| 3.6 wt. % acid-stabilized silica | 1 wt. % HPC |
| 0.18 wt. % TAZ | 2 wt. % PVP |
| 10.8 wt. % glycine | 3.5 wt. % TAZ |
| 0 to 0.1 wt. % biocide | 0 to 0.1 wt. % biocide |
| 85.32 wt. % to 85.42 wt. % water | 0 to 1 wt. % defoamer |
| | 92.4 to 93.5 wt. % water |

For the bulk copper CMP composition, 41.67 mL of Concentrate A1, 25.00 mL of 30% H₂O₂ and 83.33 mL of deionized water may be delivered to the processing tool or processing station for bulk copper removal. For the soft landing CMP composition, 41.67 mL of Concentrate A1, 15.00 mL of Concentrate B1, 25.00 mL of 30% H₂O₂ and 68.33 mL of deionized water may be delivered to the processing tool or processing station for soft landing processing.

Notably, the blending process and the concentrations described in this example are not intended to limit the scope of this invention. This blending process is readily adaptable by one skilled in the art depending on the components of the CMP compositions and the concentrations thereof. Moreover, it should be appreciated that the soft landing removal composition may be delivered to the same or a different platen as that used for bulk copper removal.

### EXAMPLE 5

Preferred copper removal CMP formulations based on formulation A herein are as follows:

Formulation E=Formulation A+5 wt. % H₂O₂

| Component | wt % |
|---|---|
| Glycine | about 3 |
| 1,2,4-triazole (TAZ) | about 0.4 |
| Polyvinylpyrrolidone (PVP) | about 0.05 |
| DP6190 (silica) | about 1 |
| Hydroxypropylcellulose (HPC) | about 0.1 |
| H₂O₂ | about 5 |
| water | about 90.3 |
| TD 1525 | about 0.15 |
| bronopol | about 0.002 |
| pH | about 5 |

Formulation F=Formulation A diluted 4.3×+2.3 wt. % H₂O₂

| Component | wt % |
|---|---|
| Glycine | about 0.83 |
| 1,2,4-triazole (TAZ) | about 0.11 |
| Polyvinylpyrrolidone (PVP) | about 0.014 |
| DP6190 (silica) | about 0.28 |
| Hydroxypropylcellulose (HPC) | about 0.028 |
| H₂O₂ | about 2.3 |
| water | about 96.3 |
| TD 1525 | about 0.04 |
| bronopol | about 0.0005 |
| pH | about 5 |

Those skilled in the art will recognize, or be able to ascertain using no more than routine experimentation, numerous equivalents to the specific examples and embodiments described herein. Such equivalents were considered to be within the scope of this invention and are covered by the following claims. The contents of all references, issued patents, and published patent applications cited throughout this application are hereby incorporated by reference.

1. A copper removal CMP slurry composition with increased planarization efficiency of copper films, comprising at least one abrasive agent, at least one solvent, at least one passivating agent and at least one polymeric additive.

2. The CMP slurry composition according to claim 1, wherein said composition is further characterized by comprising at least one of the following agents from the group consisting of at least one chelating agent, at least one rheology agent, at least one oxidizing agent, at least one buffering agent, at least one biocide, at least one defoaming agent, and combinations thereof.

3. The CMP slurry composition according to claim 1, wherein said abrasive agent comprises an acid-stable abrasive species selected from the group consisting of silica, acid-stable silica, alumina, silicon carbide, silicon nitride, iron oxide, ceria, zirconium oxide, tin oxide, titanium dioxide, organic polymer particles, epoxies, urethanes, polyesters, polyamides, polycarbonates, polyolefins, polyvinylchloride, polystyrenes, (meth)acrylics, alumina-coated colloidal silica, DP6190, and combinations thereof
wherein said passivating agent comprises a compound selected from the group consisting of 1,2,4-triazole (TAZ), benzotriazole, tolytriazole, 5-phenyl-benzotriazole, 5-nitro-benzotriazole, 3-amino-5-mercpato-1,2,4-triazole, 1-amino-1,2,4-triazole, hydroxybenzotriazole, 2-(5-amino-pentyl)-benzotriazole, 1-amino-1,2,3-triazole, 1-amino-5-methyl-1,2,3-triazole, 3-amino-1,2,4-triazole, 3-mercapto-1,2,4-triazole, 3-isopropyl-1,2,4-triazole, 5-phenylthiol-benzotriazole, halo-benzotriazoles (halo=F, Cl, Br or I), naphthotriazole, 2-mercaptobenzimidazole (MBI), 2-mercaptobenzothiazole, 4-methyl-2-phenylimidazole, 2-mercaptothiazoline, 5-aminotetrazole, 5-aminotetrazole monohydrate, 5-amino-1,3,4-thiadiazole-2-thiol, 2,4-diamino-6-methyl-1,3,5-triazine, thiazole, triazine, methyltetrazole, 1,3-dimethyl-2-imidazolidinone, 1,5-pentamethylenetetrazole, 1-phenyl-5-mercaptotetrazole, diaminomethyltriazine, imidazoline thione, mercaptobenzimidazole, 4-methyl-4H-1,2,4-triazole-3-thiol, 5-amino-1,3,4-thiadiazole-2-thiol, benzothiazole, tritolyl phosphate, imidazole, indiazole, urea and thiourea compounds, oxalic acid, malonic acid, succinic acid, nitrilotriacetic acids, iminodiacetic acids, and derivatives and combinations thereof
wherein said solvent comprises a compound selected from the group consisting of water, methanol, ethanol, propanol, butanol, ethylene glycol, propylene glycol, glycerin and combinations thereof; and
wherein said polymeric additive is selected from the group consisting of polyvinylpyrrolidone, polymers including N-vinyl pyrrolidone monomers, and combinations thereof.

4. (canceled)

5. The CMP slurry composition according to claim 2, comprising at least one rheology agent, wherein said rheology agent is selected from the group consisting of modified cellulose derivatives, cellulose ethers, starch modified cellulose derivatives, cellulose ethers, starch derivatives, pectin derivatives, polyacylamides and aqueous dispersions thereof.

6. The CMP slurry composition according to claim 2, comprising at least one oxidizing agent, wherein said oxidizing agent is selected from the group consisting of hydrogen peroxide, ferric nitrate, potassium iodate, potassium permanganate, nitric acid, ammonium chlorite, ammonium chlorate, ammonium iodate, ammonium perborate, ammonium perchlorate, ammonium periodate, tetramethylammonium chlorite, tetramethylammonium chlorate, tetramethylammonium iodate, tetramethylammonium perborate, tetramethylammonium perchlorate, tetramethylammonium periodate, 4-methylmorpholine-N-oxide, pyridine-N-oxide, urea hydrogen peroxide, and mixtures or two or more thereof.

7. The CMP slurry composition according to claim 2, comprising at least one chelating agent, wherein said chelating agent is selected from the group consisting of glycine, alanine, citric acid, acetic acid, maleic acid, oxalic acid, malonic acid, phthalic acid, succinic acid, nitrilotracetic acid, iminodiacetic acid, ethyenediamine, CDTA, EDTA, and combinations thereof.

8. The CMP slurry composition of claim 1, wherein said composition has a pH in a range of from about 4 to 6.

9. The CMP slurry composition according to claim 1, further comprising at least one chelating agent, at least one rheology agent, at least one buffering agent, and at least one oxidizing agent.

10. The CMP slurry composition according to claim 1, comprising silica, triazole and/or derivatives thereof, any polymer including the N-vinyl pyrrolidone monomer, and water.

11. The CMP slurry composition according to claim 1, comprising silica, 1,2,4-triazole, polyvinylpyrrolidone, and water.

12. The CMP slurry composition of claim 10, further comprising at least one of glycine, hydroxypropylcellulose, buffering agent, hydrogen peroxide, and combinations thereof.

13.-18. (canceled)

19. A method of polishing a wafer substrate having metal and barrier layer material deposited thereon, said method comprising contacting said wafer substrate having metal thereon at a first platen for sufficient time and under at least one metal removal CMP condition with at least one metal removal CMP slurry composition to substantially remove metal from said wafer and expose said barrier material, wherein said CMP slurry composition comprises at least one abrasive component, at least one solvent, at least one passivating agent, and at least one polymeric additive.

20. The method according to claim 19, wherein said composition is further characterized by comprising at least one of the following agents from the group consisting of at least one chelating agent, at least one rheology agent, at least one oxidizing agent, at least one buffering agent, and combinations thereof.

21. (canceled)

22. (canceled)

23. The method of claim 19, further comprising contacting the microelectronic device substrate having barrier layer material thereon on the first platen or a second platen for sufficient time and under barrier removal CMP conditions with a barrier removal CMP composition to substantially remove barrier layer material from the microelectronic device substrate, wherein the barrier removal CMP composition comprises at least one passivating agent, at least one barrier layer removal enhancer, at least one selectivity additive, at least one solvent, at least one acid-stable abrasive, and optionally at least one oxidizing agent.

24.-26. (canceled)

27. A kit comprising, in one or more containers, copper removal CMP composition reagents, wherein the copper removal CMP composition comprises at least one passivating agent, at least one polymeric additive, at least one abrasive agent and at least one solvent.

28. The kit according to claim 27, further comprising one or more additional components selected from the group consisting of at least one chelating agent and at least one rheology agent.

29. The kit according to claim 28, wherein a first container includes at least one abrasive, at least one passivating agent, at least one chelating agent, at least one solvent, optionally at least one biocide and optionally at least one defoamer, and a second container includes at least one rheology agent, at least one polymeric additive, at least one passivating agent, at least one solvent, optionally at least one biocide and optionally at least one defoamer.

30. The kit according to claim 29, wherein the first container and the second container are substantially devoid of oxidizing agent.

31. (canceled)

32. The CMP slurry composition according to claim 1, wherein said polymeric additive is selected from the group consisting of polyvinylpyrrolidone, polymers including N-vinyl pyrrolidone monomers, and combinations thereof.

33. The CMP slurry composition of claim 11, further comprising at least one of glycine, hydroxypropylcellulose, buffering agent, hydrogen peroxide, and combinations thereof.
